(19) United States
(12) Patent Application Publication
(10) Pub. No.: US 2024/0222928 A1
(43) Pub. Date: Jul. 4, 2024

(54) OPTICAL MODULE, OPTICAL ENGINE FOR IMAGE PROJECTION, GLASS DISPLAY, SAMPLE TESTING DEVICE, AND METHOD FOR MANUFACTURING OPTICAL MODULE

(71) Applicant: TDK CORPORATION, Tokyo (JP)

(72) Inventors: Hideaki FUKUZAWA, Tokyo (JP); Tomohito MIZUNO, Tokyo (JP); Tsuyoshi KOMAKI, Tokyo (JP); Takashi AOYAGI, Tokyo (JP); Ardalan HESHMATI, Saratoga, CA (US); Kit Chu LAM, Shanghai (CN)

(73) Assignee: TDK CORPORATION, Tokyo (JP)

(21) Appl. No.: 18/392,571

(22) Filed: Dec. 21, 2023

(30) Foreign Application Priority Data
Jan. 4, 2023 (JP) 2023-000175

(51) Int. Cl. H01S 5/02255; G02B 27/01; H01S 5/02253

(52) U.S. Cl. CPC H01S 5/02255; G02B 27/0172; H01S 5/02253; G02B 2027/0178

(57) ABSTRACT

The optical module includes a laser light source part in which a laser light emitting element is formed on one main surface of a first substrate, a mirror part in which an optical scanning mirror element is formed on one main surface of a second substrate, and a lens part in which an optical lens is formed on one main surface of a third substrate, wherein the first substrate and the third substrate are bonded via a metal bonding layer, and the optical module is configured for laser light emitted from the laser light emitting element to be reflected by the optical scanning mirror element via the optical lens.

### BACKGROUND OF THE INVENTION

### Field of the Invention

The present invention relates to an optical module, an optical engine for image projection, a glass display, a sample testing device, and a method for manufacturing an optical module.

Priority is claimed on Japanese Patent Application No. 2023-000175 filed Jan. 4, 2023, the content of which is incorporated herein by reference.

### Description of Related Art

Augmented reality (AR) glasses and virtual reality (VR) glasses are expected to be used as small wearable devices. In such devices, a light emitting element that emits full-color visible light is one of the main elements for rendering high-quality images. In such a device, a light emitting element independently and rapidly modulates the intensity of each of the three colors of RGB representing visible light, for example, to express a moving image in desired colors.

As such a light emitting element, Patent Document 1 discloses a light emitting element that emits a color moving image by causing a visible light laser to be incident on a waveguide and controlling the emission intensity of a laser chip of each color using an electric current. Furthermore, Patent Document 2 disclosures a modulator that causes laser light to be incident into an external modulator having a waveguide formed on a substrate having an electro-optic effect via an optical fiber and modulates the intensity of each of the three colors of RGB independently by an external modulator.

In wearable devices such as AR glasses and VR glasses, the key to their widespread use is to miniaturize the light emitting module so that each function fits within a size of a normal eyeglass. A miniaturized light emitting module that can be applied to such wearable devices is considered to have a structure in which laser light emitted from a light emitting element is directly reflected toward a display surface by a mirror without going through a waveguide or the like. For example, Patent Document 3 discloses an optical module in which a laser light emitting element and a mirror are mounted on one common substrate.

### PATENT DOCUMENTS

[Patent Document 1] Japanese Unexamined Patent Application, First Publication No. 2021-86976
[Patent Document 2] Japanese Patent No. 6728596
[Patent Document 3] United States Patent Application, Publication No. 2020-0110331

### SUMMARY OF THE INVENTION

However, since the optical module disclosed in Patent Document 3 has a configuration in which each of the laser light emitting element, the lens, and the mirror are fixed on one common substrate, it has not been possible to adjust an optical axis position of the laser light incident on the lens after the optical module is manufactured. Therefore, when the optical module is mounted on a device, there has been a problem in that adjustment of a mounting position of the optical module in order to emit laser light to a predetermined position on a display surface becomes complicated.

The present invention has been made in consideration of such circumstances, and an object thereof is to provide an optical module, an optical engine for image projection using the optical module, a glass display, a sample testing device, and a method for manufacturing an optical module, in which a laser light emitting element, an optical lens, and a mirror are each mounted on a substrate, and then optical axis adjustment can be performed.

In order to solve the above problem, the following means are provided.
(1) An optical module according to a first aspect of the present invention includes: a laser light source part in which a laser light emitting element is formed on one main surface of a first substrate; a mirror part in which an optical scanning mirror element is formed on one main surface of a second substrate; and a lens part in which an optical lens is formed on one main surface of a third substrate, wherein the first substrate and the third substrate are bonded via a metal bonding layer, and the optical module is configured for laser light emitted from the laser light emitting element to be reflected by the optical scanning mirror element via the optical lens.
(2) According to an optical module according to a second aspect of the present invention, in the first aspect, the second substrate and the third substrate may be bonded via the metal bonding layer.
(3) According to an optical module according to a third aspect of the present invention, in the first or second aspect, the metal bonding layer may contain at least gold or tin.
(4) According to an optical module according to a fourth aspect of the present invention, in any one of the first to third aspects, wherein each of the first substrate, the second substrate, and the third substrate may be made of one of a silicon substrate, an aluminum oxide substrate, an aluminum nitride substrate, and a quartz substrate.
(5) According to an optical module according to a fifth aspect of the present invention, in any one of the first to fourth aspects, the laser light emitting element may be configured to emit visible light range laser light in a wavelength range of 380 nm or more and less than 800 nm.
(6) According to an optical module according to a sixth aspect of the present invention, in any one of the first to fourth aspects, the laser light emitting element may be configured to emit near-infrared region laser light in a wavelength range of 800 nm or more and less than 1800 nm.
(7) According to an optical module according to a seventh aspect of the present invention, in any one of the first to sixth aspects, the lens part may include the optical lens and a lens holder made of silicon that supports the optical lens.
(8) According to an optical module according to an eighth aspect of the present invention, in any one of the first to seventh aspects, the laser light emitting element may include a plurality of laser light emitting elements, and the optical lens may be configured such that the laser light emitted from each of the laser light emitting elements is refracted to be focused on one point on the optical scanning mirror element.
(9) According to an optical module according to a ninth aspect of the present invention, in any one of the first to eighth aspects, a first wiring layer connected to the laser light emitting element may be formed on the first substrate.
(10) According to an optical module according to a tenth aspect of the present invention, in any one of the first to ninth aspects, a second wiring layer connected to the optical scanning mirror element may be formed on the second substrate.
(11) According to an optical module according to an eleventh aspect of the present invention, in any one of the first to tenth aspects, the optical scanning mirror element may be a MEMS device, and may be configured to arbitrarily adjust a reflection angle.
(12) According to an optical module according to a twelfth aspect of the present invention, in any one of the first to eleventh aspects, the laser light source may include a plurality of laser light source parts, and the first substrate constituting each of the laser light source parts may be bonded to the third substrate constituting the lens part via the metal bonding layer individually.
(13) According to an optical module according to a thirteenth aspect of the present invention, in any one of the first to twelfth aspects, a surface of a mirror surface portion of the optical scanning mirror element may be a concave mirror of which a cross section passing through a center point forms a parabola.
(14) An optical engine for image projection according to a fourteenth aspect of the present invention includes: the optical module according to any one of the first to thirteenth aspects; one common substrate on which the first substrate, the second substrate, and the third substrate are placed; and an integrated circuit formed on the common substrate and configured to control the laser light emitting element and the optical scanning mirror element.
(15) A glass display according to a fifteenth aspect of the present invention includes: the optical engine for image projection according to the fourteenth aspect; and a frame having an eyeglass shape, wherein the optical engine for image projection is disposed at a temple part of the frame.
(16) A sample testing device according to a sixteenth aspect of the present invention includes: the optical engine for image projection according to the fourteenth aspect; and a stage on which a sample for testing is placed, wherein the sample testing device is configured for the laser light to be radiated from the optical engine for image projection toward the stage.
(17) A method for manufacturing an optical module according to a seventeenth aspect of the present invention includes: a bonding material forming step of dipping a bonding material made of a constituent material of the metal bonding layer into an end surface of at least one of the first substrate and the third substrate, and an end surface of at least one of the second substrate and the third substrate; a placing step of arranging the laser light source part and the lens part adjacent to each other with the bonding material interposed therebetween, and arranging the lens part and the mirror part adjacent to each other; an adjusting step of reflecting the laser light emitted by the laser light emitting element by the optical scanning mirror element via the optical lens, making the reflected laser light incident on an optical detection device, adjusting relative positions of the laser light source part, the lens part, and the mirror part, and aligning an optical axis of the laser light with a lens optical axis of the optical lens and a center position of the optical scanning mirror element; and a joining step of radiating heat ray to melt the bonding material and respectively bonding the first substrate and the second substrate, and the second substrate and the third substrate at positions adjusted in the adjusting step.
(18) According to a method for manufacturing an optical module according to an eighteenth aspect of the present invention, in the method for manufacturing an optical module according to the seventeenth aspect, the heat ray may be an infrared laser light radiated from a YAG laser device.

According to the present invention, it is possible to provide an optical module, an optical engine for image projection using the optical module, a glass display, a sample testing device, and a method for manufacturing an optical module, in which a laser light emitting element, an optical lens, and a mirror are each mounted on a substrate, and then optical axis adjustment can be performed.

### BRIEF DESCRIPTION OF THE DRAWINGS

FIG. 1 is an external perspective view showing an optical module according to a first embodiment of the present invention.

FIG. 2 is a cross-sectional view of the optical module shown in FIG. 1.

FIG. 3 is a flowchart showing a method for manufacturing an optical module according to the present embodiment in a stepwise manner.

FIG. 4 is an external perspective view showing an optical module according to a second embodiment of the present invention.

FIG. 5 is a schematic diagram showing an operation of an optical scanning mirror element according to the second embodiment of the present invention.

FIG. 6 is a schematic diagram showing an operation of an optical scanning mirror element having another configuration according to the second embodiment of the present invention.

FIG. 7 is an external perspective view showing an optical engine for image projection according to an embodiment of the present invention.

FIG. 8 is an enlarged perspective view of a main portion showing a glass display according to an embodiment of the present invention.

FIG. 9 is an enlarged perspective view of a main portion showing a sample testing device according to an embodiment of the present invention.

### DETAILED DESCRIPTION OF THE INVENTION

An optical module according to an embodiment of the present invention, an optical engine for image projection, a glass display, a sample testing device, and a method for manufacturing the optical module which use the same will be described below with reference to the drawings. The embodiments shown below are specifically described in order to allow better understanding of the gist of the invention, and unless otherwise specified, the embodiments are not intended to limit the invention. In addition, in the drawings used in the following description, in order to make features of the present invention easier to understand, main portions may be shown enlarged for convenience, and dimensional ratios of each component are not necessarily the same as in reality.

### Optical Module: First Embodiment

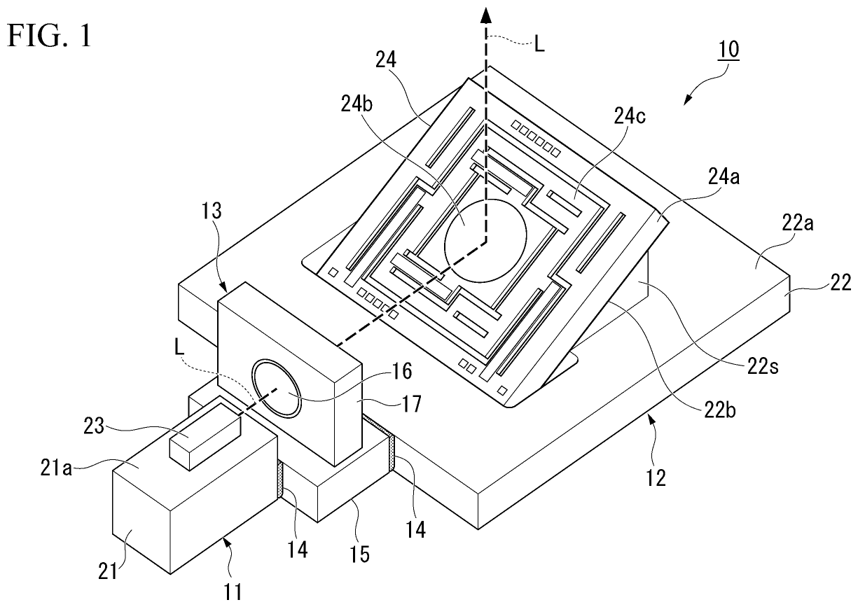

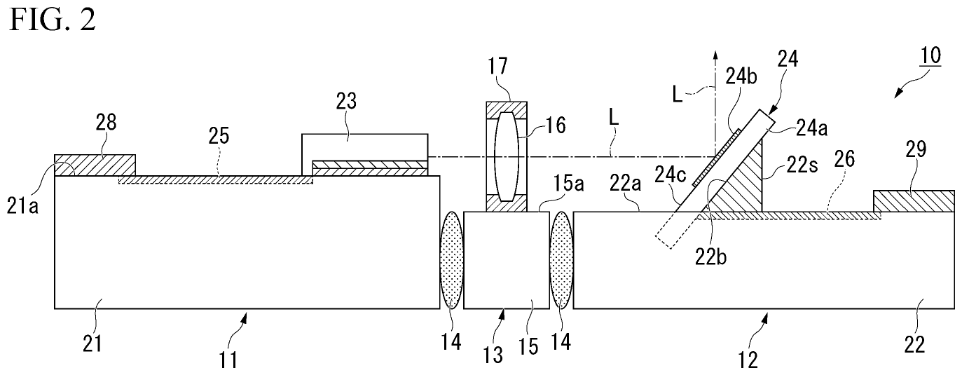

FIG. 1 is an external perspective view showing an optical module according to a first embodiment of the present invention. Moreover, FIG. 2 is a cross-sectional view of the optical module shown in FIG. 1.

The optical module 10 of this embodiment includes a laser light source part 11, a mirror part 12, a lens part 13, and a metal bonding layer 14.

The laser light source part 11 includes a first substrate (a subcarrier) 21 and a laser light emitting element 23 formed on one main surface 21a of the first substrate 21.

The first substrate 21 is configured of a silicon (Si) substrate, an aluminum oxide (Al₂O₃) substrate, an aluminum nitride (AlN) substrate, a quartz (SiO₂) substrate, or the like. The first substrate 21 may be made of the same material as a second substrate 22 constituting the mirror part 12, or may be made of a different material from the second substrate 22.

The laser light emitting element 23 is configured of an element capable of emitting laser light L, for example, an LED. The laser light emitting element 23 may be able to emit laser light L of any wavelength according to an object on which the laser light L is incident.

For example, as the laser light emitting element 23, a visible light LED element capable of emitting laser light in a visible light range, such as red laser light, green laser light, or blue laser light with a wavelength range of 380 nm or more and less than 800 nm can be used. Further, for example, as the laser light emitting element 23, an infrared LED element capable of emitting laser light in a near-infrared region with a wavelength range of 800 nm or more and less than 1800 nm can be used.

The laser light emitting element 23 is bonded to the first substrate 21 via, for example, a metal layer 27. The metal layer 27 may be configured of two metal layers including, for example, a first metal layer 27a and a second metal layer 27b. Such a metal layer 27 can be formed by a known method such as sputtering, vapor deposition, or application of a metal paste.

The first metal layer 27a may be made of, for example, an alloy of gold (Au) and tin (Sn), an alloy of tin (Sn) and copper (Cu), an alloy of indium (In) and bismuth (Bi), a tin (Sn)-silver (Ag)-copper (Cu) based solder alloy (SAC), or the like. The second metal layer 27b may be made of, for example, gold (Au), platinum (Pt), silver (Ag), lead (Pb), indium (In), nickel (Ni), or the like.

A first wiring layer 25 of which one end side is connected to the laser light emitting element 23 is formed on the one main surface 21a of the first substrate 21. The first wiring layer 25 is an electric wiring for supplying a driving current to the laser light emitting element 23, and may be a pattern wiring formed by forming a metal thin film made of gold, silver, aluminum, or the like in a predetermined pattern, for example. A first electrode (an electrode pad) 28 may be formed on the other end side of the first wiring layer 25. The first electrode (the electrode pad) 28 is connected to, for example, an external drive power source or a control integrated circuit.

The mirror part 12 includes a second substrate (a subcarrier) 22 and an optical scanning mirror element 24 formed on one main surface 22a of the second substrate 22.

The second substrate 22 is configured of a silicon (Si) substrate, an aluminum oxide (Al₂O₃) substrate, an aluminum nitride (AlN) substrate, a quartz (SiO₂) substrate, or the like. The second substrate 22 has an inclined part 22S having an inclined surface 22b inclined at a predetermined angle, for example, 45 degrees, with respect to the one main surface 22a.

The inclined part 22S of the inclined part 22S is formed so that a part of the inclined surface 22b extends to a deeper position in a thickness direction than the one main surface 22a. The optical scanning mirror element 24 is placed on the inclined surface 22b of the inclined part 22S. An angle of inclination of the inclined surface 22b with respect to the one main surface 22a may be within a range of, for example, 10° to 70°.

The optical scanning mirror element (a MEMS mirror) 24 is, for example, a micro electro mechanical system (MEMS) device obtained by finely processing a silicon wafer. The optical scanning mirror element 24 of this embodiment includes a mirror surface portion 24b having a circular shape and disposed at the center of a base body 24a, a beam portion 24c that supports the mirror surface portion 24b, and an application electrode (not shown) that bends the beam portion 24c. A surface (a reflection surface) of the mirror surface portion 24b is, for example, formed in a planar shape. Although the mirror surface portion 24b is formed in a circular shape in this embodiment, it is not limited to a circular shape, and may be formed in any shape, such as a rectangular or polygonal shape.

Such an optical scanning mirror element 24 generates an electrostatic force by applying a predetermined voltage to the application electrode. Then, the beam portion 24c is locally bent according to a position at which the electrostatic force is generated, thereby changing an angle of the mirror surface portion 24b supported by the beam portion 24c two-dimensionally (a horizontal direction (an X direction) and a vertical direction (a Y direction)). A reflection angle of the laser light L reflected by the mirror surface portion 24b is changed by changing the angle of the mirror surface portion 24b. That is, due to the laser light L being scanned from the mirror surface portion 24b, arbitrary characters or figures can be displayed on the display surface by the laser light L.

A second wiring layer 26 of which one end side is connected to the optical scanning mirror element 24 is formed on the one main surface 22a of the second substrate 22. The second wiring layer 26 is an electric wiring for supplying a drive current that changes an angle of the mirror surface portion 24b of the optical scanning mirror element 24, and may be a pattern wiring formed by forming a metal thin film made of gold, silver, aluminum, or the like in a predetermined pattern, for example. A second electrode (an electrode pad) 29 may be formed on the other end side of the second wiring layer 26. The second electrode (the electrode pad) 29 is connected to, for example, an external drive power source or a control integrated circuit.

The lens part 13 includes a third substrate (a subcarrier) 15, an optical lens 16 formed on one main surface 15a of the third substrate 15, and a lens holder 17 that supports the optical lens 16.

The third substrate 15 is configured of a silicon (Si) substrate, an aluminum oxide (Al₂O₃) substrate, an aluminum nitride (AlN) substrate, a quartz (SiO₂) substrate, or the like. The first substrate 21 may be made of the same material as the first substrate 21 constituting the laser light source part 11 and the second substrate 22 constituting the mirror part 12, and may be made of a different material from the first substrate 21 and the second substrate 22.

The optical lens 16 may be, for example, a convex lens that narrows the laser light L emitted from the laser light emitting element 23 to further improve directivity. Further, the lens holder 17 is made entirely of silicon, for example, and comes into contact with a peripheral edge of the optical lens 16 to support the optical lens 16.

The laser light source part 11, the lens part 13, and the mirror part 12 that constitute the optical module 10 are disposed in a straight line. The first substrate 21 that constitutes the laser light source part 11 and the third substrate 15 that constitutes the lens part 13, and the third substrate 15 and the second substrate 22 constituting the mirror part 12 are respectively directly bonded to each other via the metal bonding layer 14. That is, the laser light source part 11 and the mirror part 12 are integrated by the metal bonding layer 14 with the lens part 13 interposed therebetween, and constitute the optical module 10.

The metal bonding layer 14 is made of a metal material that can be bonded to the constituent material of the first substrate 21, the constituent material of the second substrate 22, and the constituent material of the third substrate 15, for example, a metal material containing at least gold or tin. More specifically, as gold-based solder materials, a gold-tin solder (Au—Sn), a gold-germanium solder (Au—Ge), a gold-silicon solder (Au—Si), and the like may be used. Further, as tin-based solder materials, an eutectic solder (Sn—Pb), a lead-free solder (Sn—Ag), a copper-tin solder (Sn—Cu), or the like may be used. The constituent materials of the metal bonding layers 14 may be appropriately selected according to the constituent materials of the first substrate 21, second substrate 22, and third substrate 15.

The metal bonding layer 14 is not limited to one layer. For example, when the first substrate 21 and the third substrate 15 are made of different materials, the first substrate 21 and the third substrate 15 may be bonded by a two-layer metal bonding layer using metal materials that are optimal for bonding the respective substrate materials. Further, for example, when the second substrate 22 and the third substrate 15 are made of different materials, the second substrate 22 and the third substrate 15 may be bonded by a two-layer metal bonding layer using metal materials that are optimal for bonding the respective substrate materials. Alternatively, three or more metal bonding layers may be formed using different materials.

Further, in this embodiment, although the first substrate 21 and the third substrate 15, and the second substrate 22 and the third substrate 15 are respectively bonded by the metal bonding layer 14, in the optical module of the present invention, at least only the first substrate 21 and the third substrate 15 may be bonded by the metal bonding layer 14. In such a configuration, the second substrate 22 and the third substrate 15 may be bonded using various adhesives other than the metal bonding layer 14, and a single substrate may be used without separating it into the second substrate 22 and the third substrate 15, and the optical lens and the optical scanning mirror element may be disposed on the single substrate.

### [Method for Manufacturing Optical Module]

A method of manufacturing the optical module of the first embodiment configured as above, and an operation and effects of the optical module of the first embodiment will be described.

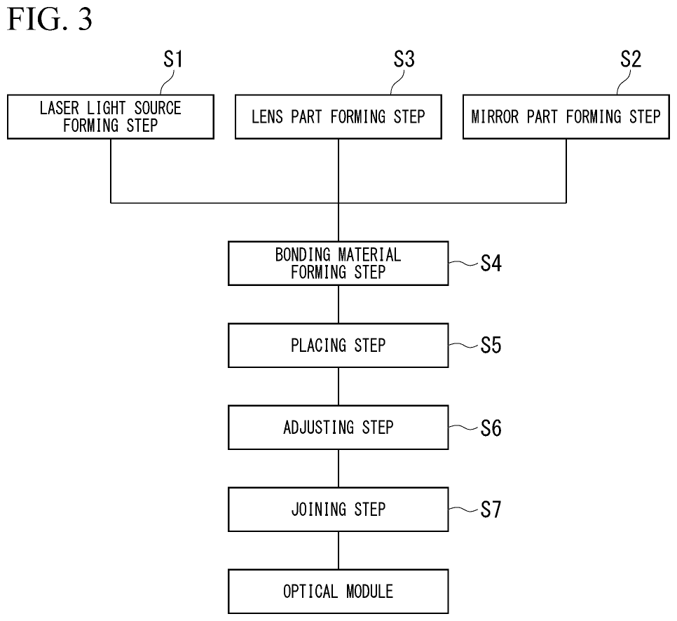

FIG. 3 is a flowchart showing the method for manufacturing the optical module of this embodiment in a stepwise manner.

When the optical module 10 of the first embodiment is manufactured, first, the laser light emitting element 23 is bonded to one main surface 21a of the first substrate 21 via the metal layer 27. Further, the first wiring layer 25 and the first electrode 28 are formed on the one main surface 21a of the first substrate 21. Thus, the laser light source part 11 is obtained (laser light source part forming step S1).

Further, the optical scanning mirror element 24 is bonded to the inclined surface 22b of the inclined part 22S constituting the second substrate 22, for example, via an adhesive layer. Further, the second wiring layer 26 and the second electrode 29 are formed on one main surface 22a of the second substrate 22. Thus, the mirror part 12 is obtained (mirror part forming step S2).

Further, the lens holder 17 that has supported the optical lens 16 is bonded to one main surface 15a of the third substrate 15, for example, via an adhesive layer. Thus, the lens part 13 is obtained (lens part forming step S3).

Next, a bonding material made of the constituent material of the metal bonding layer 14 is dipped into at least one or both of an end surface of the first substrate 21 constituting the laser light source part 11 and one end surface (an end surface facing the first substrate 21) of the third substrate 15 constituting the lens part 13. Further, a bonding material made of the constituent material of the metal bonding layer 14 is dipped into at least one or both of an end surface of the second substrate 22 constituting the mirror part 12 and the other end surface (an end surface facing the second substrate 22) of the third substrate 15 constituting the lens part 13 (bonding material forming step S4). In this embodiment, the bonding material is dipped into one end surface and the other end surface of the third substrate 15 constituting the lens part 13.

Next, the laser light source part 11, the lens part 13, and the mirror part 12 are disposed (temporarily disposed) adjacent to each other with each of the bonding materials interposed therebetween (placing step S5).

Next, a power source is connected to the laser light emitting element 23 via the first wiring layer 25 to drive the laser light emitting element 23, and the laser light Lis radiated through the optical lens 16 forming the lens part 13 toward the mirror surface portion 24b of the optical scanning mirror element 24 forming the mirror part 12. Further, the laser light L reflected by the mirror surface portion 24b is made incident on an optical detection device, for example, a photodetector. Then, in this state, the first substrate 21, the second substrate 22, and the third substrate 15 are positioned with respect to each other. That is, relative positions of the laser light source part 11, the lens part 13, and the mirror part 12 are adjusted with reference to measured values of the photodetector so that an optical axis of the laser light L is aligned with a lens optical axis of the optical lens 16 and a center position of the mirror surface portion 24b of the optical scanning mirror element 24 (adjusting step S6).

In the embodiment, the optical axis of the laser light L emitted from the laser light emitting element 23 is aligned with the lens optical axis of the optical lens 16 and the center position of the mirror surface portion 24b of the optical scanning mirror element 24 by moving the relative position of the laser light source part 11 with respect to the lens part 13 and the mirror part 12.

Then, at the positions adjusted in the adjusting step S6, heat rays are radiated toward each of one end surface and the other end surface of the second substrate 22 to melt the respective bonding materials. Then, the end surfaces of the first substrate 21 and the third substrate 15, and the end surfaces of the second substrate 22 and the third substrate 15 are respectively bonded to each other via the respective metal bonding layers 14 formed by cooling and solidifying the melted bonding materials (joining step S7). The heat rays used in the joining step S7 may be, for example, solid laser light mainly having a wavelength of 1064 μm emitted from a YAG laser device.

Through the steps described above, the optical module 10 of the first embodiment can be manufactured.

According to the optical module 10 of the first embodiment, since a substrate (the first substrate 21) on which the laser light emitting element 23 is placed, a substrate (the second substrate 22) on which the optical scanning mirror element 24 is placed, and a substrate (the third substrate 15) on which the optical lens 16 is placed are each separate substrates, and the three substrates are bonded to each other via the metal bonding layers 14, the optical axis position of the laser light L can be aligned so that during manufacturing, the relative positions of the first substrate 21, the second substrate 22, and the third substrate 15 are adjusted, and alignment of the optical axis of the laser light L can be performed so that the optical axis of the laser light L can be aligned with each of the lens optical axis of the optical lens 16 and the center position of the mirror surface portion 24b of the optical scanning mirror element 24 (active alignment).

Thus, for example, compared to a conventional optical module in which a laser light emitting element, an optical lens, and a mirror element are all mounted on one common substrate, it is possible to obtain the optical module 10 that can radiate the laser light L having a high intensity of light with high positional accuracy.

Further, since the substrate (the first substrate 21) on which the laser light emitting element 23 is placed, the substrate (the second substrate 22) on which the optical scanning mirror element 24 is placed, and the substrate (the third substrate 15) on which the optical lens 16 is placed are configured as separate substrates, the optical module of the second embodiment which will be described below can be easily manufactured.

### Optical Module: Second Embodiment

Next, a configuration of an optical module of a second embodiment will be described. Components similar to those in the first embodiment are given the same numbers and redundant descriptions will be omitted.

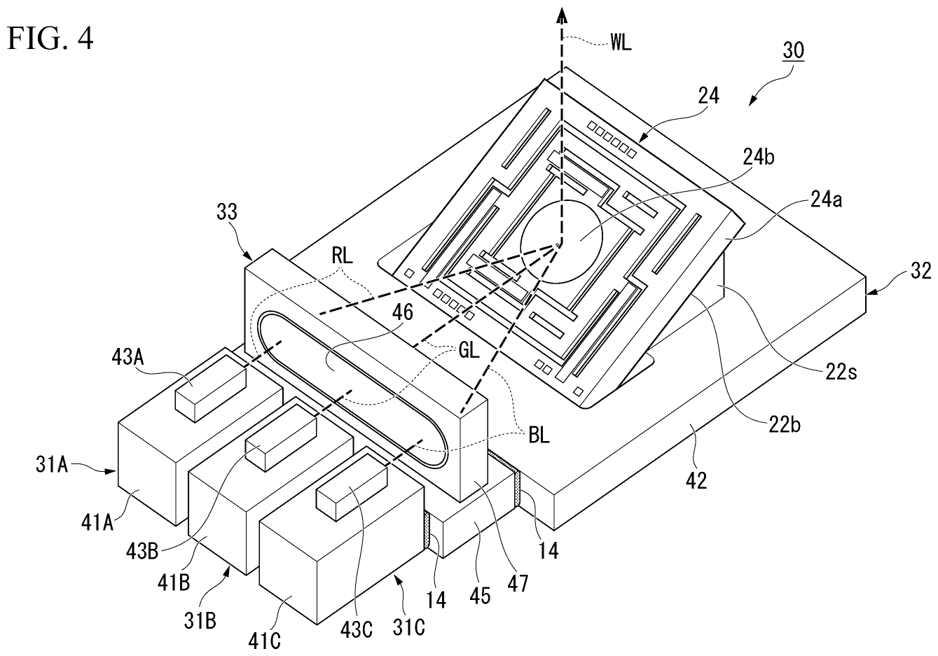

FIG. 4 is an external perspective view showing the optical module according to the second embodiment of the present invention.

In the optical module 30 of the second embodiment, first substrates 41A, 41B, and 41C which respectively constitute three laser light source parts 31A, 31B, and 31C are bonded to a third substrate 45 constituting one lens part 33 via metal bonding layers 14. Additionally, the third substrate 45 of the lens part 33 is bonded to the second substrate 42 constituting one mirror part 32 via the metal bonding layer 14.

A laser light emitting element 43A that constitutes the laser light source part 31A is configured of, for example, a red LED that emits red laser light RL. Further, a laser light emitting element 43B that constitutes the laser light source part 31B is configured of, for example, a green LED that emits green laser light GL. Furthermore, a laser light emitting element 43C that constitutes the laser light source part 31C is configured of, for example, a blue LED that emits blue laser light BL.

Further, an optical lens 46 constituting the lens part 33 is an aspherical lens with an elliptical exterior, and focuses a plurality of laser lights RL, GL, and BL that are incident from mutually different directions toward the center of the mirror surface portion 24b of the optical scanning mirror element 24.

The laser light emitted from each of the laser light source parts 31A, 31B, and 31C is focused through the optical lens 46 forming the lens part 33 toward the center of the mirror surface portion 24b of the optical scanning mirror element 24 forming the mirror part 32. Additionally, a surface of the mirror surface portion 24b of the optical scanning mirror element 24 is, for example, a reflective surface (a concave mirror) having a concave surface.

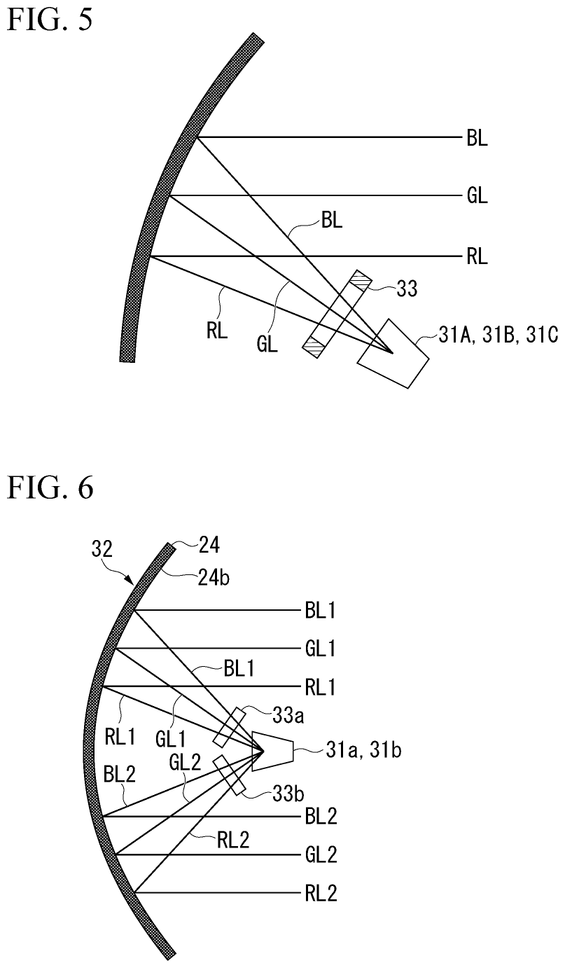

More specifically, as shown in FIG. 5, a cross section of the optical scanning mirror element 24 that passes through the center of the mirror surface portion 24b is a concave mirror having a parabolic shape. In this way, the laser lights RL, GL, and BL emitted from the laser light source parts 31A, 31B, and 31C of which laser light emission positions are different from each other are incident on the surface of the mirror surface portion 24b of the optical scanning mirror element 24 through the lens part 33 at different angles from each other. However, as in this embodiment, the laser lights RL, GL, and BL that are incident at mutually different angles can be reflected as parallel lights that are parallel to each other by making the surface of the mirror surface portion 24b of the optical scanning mirror element 24 a reflecting surface (the concave mirror) having a concave surface.

Thus, even when the respective emission positions of the laser lights RL, GL, and BL are different, as long as a physical distance and a positional relationship between projection positions of the mirror surface portion 24b are fixed, it becomes possible to radiate the laser lights RL, GL, and BL parallel to each other toward any one region.

According to the optical module 30 of the second embodiment, an image of any color tone, for example, a full color image, can be displayed on an external display surface due to the laser light WL reflected by the mirror surface portion 24b of the optical scanning mirror element 24 by performing scanning of each of the laser light source parts 31A, 31B, and 31C at arbitrary timings.

Additionally, also in such an optical module 30, when the optical module 30 is manufactured, alignment of the optical axis positions can be performed between the laser light source parts 31A, 31B, and 31C and the optical lens 46 by configuring the first substrates 41A, 41B, and 41C to be bonded to one third substrate 45 via the metal bonding layers 14 (the active alignment). Thus, it is now possible to accurately focus the three laser lights RL, GL, and BL toward one point, such as the center of the mirror surface portion 24b of the optical scanning mirror element 24 and to display a clear and blur-free full-color image on an external display surface.

Furthermore, according to the optical module 30 of the second embodiment, since the configuration is such that the laser lights emitted from the laser light source parts 31A, 31B, and 31C are focused on the center of the mirror surface portion 24b of the optical scanning mirror element 24 via the optical lens 46, as in the related art, there is no need for an optical waveguide unit for coupling multiple laser lights, and it is possible to realize a compact and lightweight optical module 30 that corresponds to a full-color image.

As a modified example of the second embodiment, as shown in FIG. 6, when a concave mirror of which the cross section passing through the center of the mirror surface portion 24b of the optical scanning mirror element 24 forms a parabola is used, the configuration has two sets of three R, G, and B laser light source parts, and three laser lights RL1, GL1, and BL1 may be emitted from one set of laser light source parts 31a and are reflected at a region near the center of the mirror surface portion 24b via the lens part 33a. Further, three laser lights RL2, GL2, and BL2 may be emitted from the other set of laser light source parts 31b and are reflected at another region near the center of the mirror surface portion 24b via the lens part 33b.

Thus, two sets of RGB laser lights parallel to each other and configured of the laser lights RL1, GL1, BL1 and RL2, GL2, BL2 parallel to each other can be radiated on an external display surface or the like.

### [Optical Engine for Image Projection]

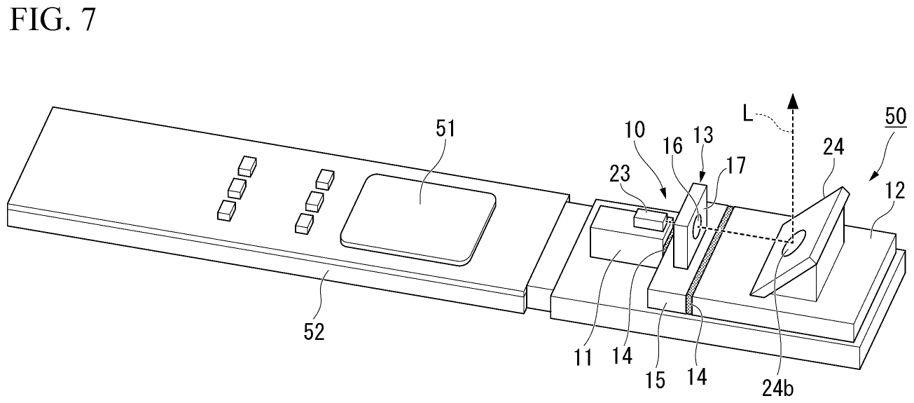

Next, a configuration of the optical engine for image projection according to an embodiment of the present invention will be described. Components similar to those of the optical module of the first embodiment are given the same numbers, and redundant descriptions will be omitted. FIG. 7 is an external perspective view showing the optical engine for image projection according to the embodiment of the present invention.

The optical engine 50 for image projection of this embodiment includes the optical module 10 of the first embodiment, an integrated circuit 51, and a common substrate 52.

The integrated circuit 51 performs control of light emission of the laser light emitting element 23 (refer to FIGS. 1 and 2) constituting the laser light source part 11 and control of an angle of the optical scanning mirror element 24 (refer to FIGS. 1 and 2) constituting the mirror part 12.

The common substrate 52 forms one common substrate on which the first substrate 21 constituting the laser light source part 11, the second substrate 22 constituting the mirror part 12, and the third substrate 15 constituting the lens part 13 are placed.

According to such an optical engine 50 for image projection, it functions as a laser image projection means that is miniaturized and compact. For example, by incorporating such an optical engine 50 for image projection into a wearable device, it is possible to realize a wearable device that can project a clear image while ensuring a comfortable wearing feeling without incompatibility.

### [Glass Display]

Next, the configuration of the optical engine for image projection according to an embodiment of the present invention will be described. Components similar to those of the optical engine for image projection of the embodiment described above are given the same numbers, and redundant descriptions will be omitted.

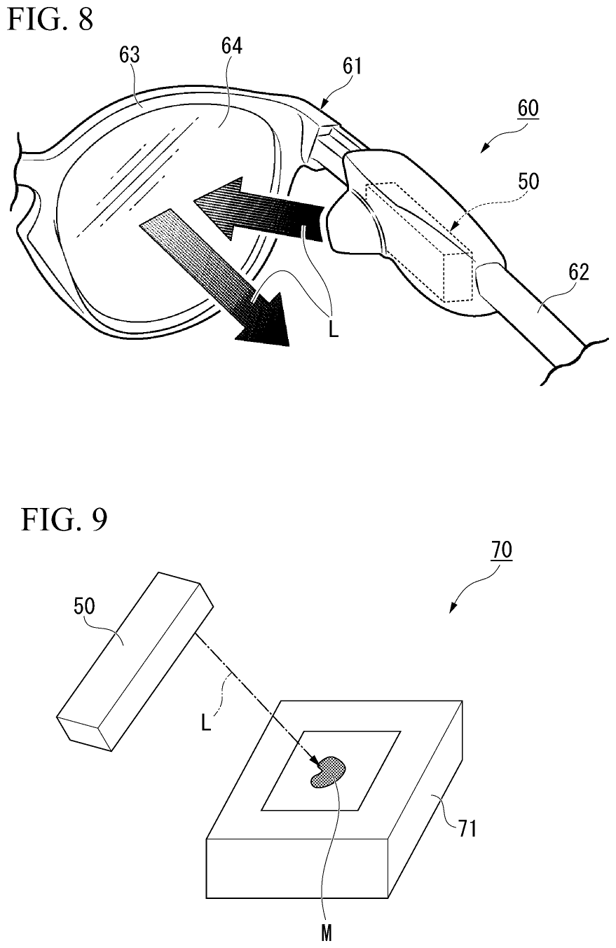

FIG. 8 is an enlarged perspective view of a main portion of a glass display according to the embodiment of the present invention.

The glass display 60 of this embodiment includes the optical engine 50 for image projection of the embodiment described above and a frame 61 having an eyeglass shape.

A miniaturized optical engine 50 for image projection is built in a temple part 62 constituting the frame 61.

The optical engine 50 for image projection emits laser light constituting image light toward a glass 64 supported by a front frame 63 constituting the frame 61. The glass 64 is, for example, a half mirror, and an image formed by the laser light L emitted from the optical engine 50 for image projection is projected onto the glass 64. A wearer of the glass display 60 can directly observe an image projected on an inner surface of the glass 64.

As described above, according to the glass display 60 of this embodiment, it is possible to realize a glass display 60 that maintains a good wearing feeling without greatly expanding the temple part 62 of the frame 61 having an eyeglass shape which has a space limitation using the optical engine 50 for image projection that is compact and lightweight.

### [Sample Testing Device]

Next, a configuration of a sample testing device according to an embodiment of the present invention will be described. The same components as those of the optical engine for image projection of the embodiment described above are given the same numbers, and redundant descriptions will be omitted.

FIG. 9 is an enlarged perspective view of a main portion showing the sample testing device according to an embodiment of the present invention.

The sample testing device 70 of this embodiment includes the optical engine 50 for image projection of the embodiment described above and a stage 71 on which a sample for testing is placed.

The optical engine 50 for image projection emits a laser light having a wavelength that acts on a sample, for example, a near-infrared region laser light having a wavelength range of 800 nm or more and less than 1800 nm toward the stage 71. The sample M placed on the stage 71 undergoes a specific reaction by the near-infrared region laser light L radiated from the optical engine 50 for image projection. It becomes possible to analyze a composition, a lesion, or the like of the sample by analyzing the sample after such a reaction due to the laser light.

According to the sample testing device 70 of this embodiment, it is possible to realize a sample testing device 70 that is small and low-cost and performs optical analysis of a living body, or the like using the optical engine 50 for image projection that is compact and lightweight.

Although one embodiment of the present invention has been described above, this embodiment is presented as an example and is not intended to limit the scope of the invention. This embodiment can be implemented in various other forms, and various omissions, substitutions, and changes can be made without departing from the gist of the invention. This embodiment and modifications thereof are included within the scope and gist of the invention as well as within the scope of the invention described in the claims and the equivalents thereof.

### EXPLANATION OF REFERENCES

10 Optical module
11 Laser light source part
12 Mirror part
13 Lens part
14 Metal bonding layer
15 Third substrate (subcarrier)
16 Optical lens
17 Lens holder
21 First substrate (subcarrier)
22 Second substrate (subcarrier)
23 Laser light emitting element
24 Optical scanning mirror element (MEMS mirror)

What is claimed is:

1. An optical module comprising:
a laser light source part in which a laser light emitting element is formed on one main surface of a first substrate;
a mirror part in which an optical scanning mirror element is formed on one main surface of a second substrate; and
a lens part in which an optical lens is formed on one main surface of a third substrate,
wherein the first substrate and the third substrate are bonded via a metal bonding layer, and
the optical module is configured for laser light emitted from the laser light emitting element to be reflected by the optical scanning mirror element via the optical lens.

2. The optical module according to claim 1, wherein the second substrate and the third substrate are bonded via the metal bonding layer.

3. The optical module according to claim 1, wherein the metal bonding layer contains at least gold or tin.

4. The optical module according to claim 1, wherein each of the first substrate, the second substrate, and the third substrate is made of one of a silicon substrate, an aluminum oxide substrate, an aluminum nitride substrate, and a quartz substrate.

5. The optical module according to claim 1, wherein the laser light emitting element is configured to emit visible light range laser light in a wavelength range of 380 nm or more and less than 800 nm.

6. The optical module according to claim 1, wherein the laser light emitting element is configured to emit near-infrared region laser light in a wavelength range of 800 nm or more and less than 1800 nm.

7. The optical module according to claim 1 wherein the lens part includes the optical lens and a lens holder made of silicon that supports the optical lens.

8. The optical module according to claim 1, wherein the laser light emitting element comprises a plurality of laser light emitting elements, and the optical lens is configured such that the laser light emitted from each of the laser light emitting elements is refracted to be focused on one point on the optical scanning mirror element.

9. The optical module according to claim 1 wherein a first wiring layer connected to the laser light emitting element is formed on the first substrate.

10. The optical module according to claim 1, wherein a second wiring layer connected to the optical scanning mirror element is formed on the second substrate.

11. The optical module according to claim 1, wherein the optical scanning mirror element is a MEMS device, and is configured to arbitrarily adjust a reflection angle.

12. The optical module according to claim 1, wherein the laser light source comprises a plurality of laser light source parts, and the first substrate constituting each of the laser light source parts is bonded to the third substrate constituting the lens part via the metal bonding layer individually.

13. The optical module according to claim 1, wherein a surface of a mirror surface portion of the optical scanning mirror element is a concave mirror of which a cross section passing through a center point forms a parabola.

14. An optical engine for image projection comprising:
the optical module according to claim 1;
one common substrate on which the first substrate, the second substrate, and the third substrate are placed; and
an integrated circuit formed on the common substrate and configured to control the laser light emitting element and the optical scanning mirror element.

15. A glass display comprising:
the optical engine for image projection according to claim 14; and
a frame having an eyeglass shape,
wherein the optical engine for image projection is disposed at a temple part of the frame.

16. A sample testing device comprising:
the optical engine for image projection according to claim 14; and
a stage on which a sample for testing is placed,
wherein the sample testing device is configured for the laser light to be radiated from the optical engine for image projection toward the stage.

17. A method for manufacturing the optical module according to claim 2, comprising:
a bonding material forming step of dipping a bonding material made of a constituent material of the metal bonding layer into an end surface of at least one of the first substrate and the third substrate, and an end surface of at least one of the second substrate and the third substrate;
a placing step of arranging the laser light source part and the lens part adjacent to each other with the bonding material interposed therebetween, and arranging the lens part and the mirror part adjacent to each other;
an adjusting step of reflecting the laser light emitted by the laser light emitting element by the optical scanning mirror element via the optical lens, making the reflected laser light incident on an optical detection device, adjusting relative positions of the laser light source part, the lens part, and the mirror part, and aligning an optical axis of the laser light with a lens optical axis of the optical lens and a center position of the optical scanning mirror element; and
a joining step of radiating heat ray to melt the bonding material and respectively bonding the first substrate and the second substrate, and the second substrate and the third substrate at positions adjusted in the adjusting step.

18. The method for manufacturing the optical module according to claim 17, wherein the heat ray is an infrared laser light radiated from a YAG laser device.
